(19) United States
(12) Patent Application Publication
(10) Pub. No.: US 2010/0001400 A1
(43) Pub. Date: Jan. 7, 2010

(54) SOLDER CONTACT

(76) Inventors: Hartmut Schmidt, Munchen (DE); Andreas Krause, Dresden (DE); Bernd Bitnar, Freiberg (DE)

Correspondence Address: MCGLEW & TUTTLE, PC, P.O. BOX 9227, SCARBOROUGH STATION, SCARBOROUGH, NY, 10510-9227, US

(21) Appl. No.: 12/496,958

(22) Filed: Jul. 2, 2009

(30) Foreign Application Priority Data
Jul. 5, 2008 (DE) 10 2008 031 836.1

(51) Int. Cl. H01L 23/488; H01L 21/60

(52) U.S. Cl. 257/751; 438/612; 257/762; 257/772; 257/E23.023; 257/E21.509

(57) ABSTRACT

A low melting temperature solder is provided for producing a solder contact between a connection element and a contact structure of a semiconductor component.

### BACKGROUND OF THE INVENTION

1. Field of the Invention

The invention relates to a semiconductor component, in particular a solar cell comprising a solder contact, and a method of producing the same.

2. Background Art

When assembling photovoltaic modules, several solar cells need to be brought into contact. This is usually performed by soldering conductive contact strips thereto. To this end, the solder needs to be heated at least to its melting temperature. Due to the fact that the elements of a solar cell, in particular the semiconductor substrate which usually consists of silicon, and the contact strip which usually consists of copper, have different thermal expansion coefficients, mechanical stresses will occur in the solar cell when the latter cools down to ambient temperature; the higher the solidification temperature of the solder, the greater the mechanical stresses. These stresses may cause warping of the solar cells or even cracking of the contact or the solar cell.

In the subsequent processing step, the so-called module embedding of the soldered solar cells, the solar cells are heated up again. This may cause damage to the solder contacts. It is therefore common practice to use solders whose melting point is considerably above the embedding temperature.

### SUMMARY OF THE INVENTION

It is therefore the object of the invention to improve the solder contact of a semiconductor component. It is the object of the invention to provide a method for the production of an improved solder contact for a semiconductor component.

These objects are achieved by a semiconductor component comprising at least one semiconductor substrate comprising at least one contact structure arranged on the semiconductor substrate, and at least one electrically conducting connection element for establishing electrical contact in the contact structure, with the at least one connection element being connected to the at least one contact structure in an electrically conducting manner by means of a solder contact, and with the solder contact being at least partially formed by a low melting temperature solder.

Furthermore, these objects are achieved by a method for the production of a solder contact with a semiconductor component, the method comprising the steps of providing the semiconductor component comprising at least one contact structure and at least one electrically conducting connection element, and soldering the at least one connection element to the at least one contact structure, with a low melting temperature solder being used for soldering.

The gist of the invention is that in order to electrically connect a semiconductor component, in particular a solar cell, the terminals thereof are conductively connected to the designated areas of its contact structure by means of a solder with a low melting temperature. The solder advantageously has a melting temperature of less than 230° C., in particular less than 180° C., preferably less than 150° C. This substantially reduces thermally induced mechanical stresses in the semiconductor substrate. Compared to electrically conductive adhesives, the solders according to the invention are much cheaper and, what is more, easier to process. The properties of the contact structure described below ensure a trouble-free re-melting of the solder contact for module embedding.

Features and details of the invention will become apparent from the description of an embodiment by means of the drawing.

### BRIEF DESCRIPTION OF THE DRAWING

FIG. 1 is a diagrammatic view of a semiconductor component according to an embodiment.

### DESCRIPTION OF THE PREFERRED EMBODIMENT

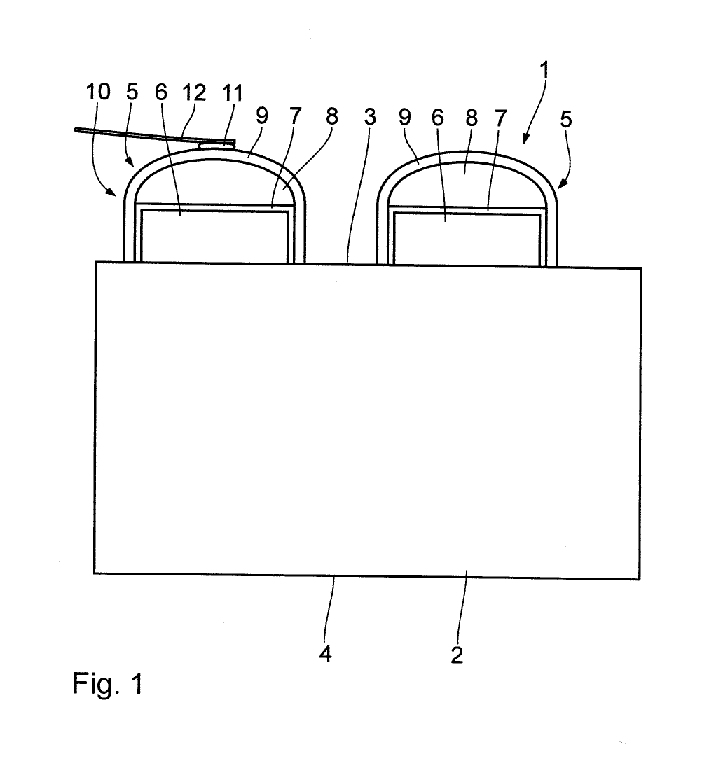

The following is a description of an embodiment of the invention with reference to FIG. 1. A semiconductor component 1, for instance a solar cell, comprises a semiconductor substrate 2. The semiconductor substrate 2 is flat, in other words two-dimensional, and comprises a front side 3 and a back side 4. The semiconductor substrate 2 in particular consists of silicon. Other semiconductor materials are conceivable as well.

The semiconductor component comprises contact structures 5 on the front side 3 of the semiconductor substrate 2. A detailed description of the design of the contact structure 5 can be found in DE 10 2007 031 958.6, in DE 10 2007 038 744.1, and in DE 10 2008 015 452.0. The contact structure 5 is comprised of several layers. It comprises a seed layer 6 which is applied to the semiconductor substrate 2. Furthermore, the contact structure 5 comprises a diffusion barrier 7 which is arranged on said seed layer 6, a conductive layer 8 which is arranged on said diffusion barrier 7 and an anti-corrosion layer 9 which is arranged on said conductive layer 8. The seed layer 6, the diffusion barrier 7, the conductive layer 8 and the anti-corrosion layer 9 together form the contact structure 5.

The seed layer 6, which is arranged on the front side 3 of the semiconductor substrate 2, is in electrical contact with the semiconductor substrate 2. It consists of an electrically conducting material, in particular of a metal, which has an extremely low diffusion coefficient with respect to the material of the semiconductor substrate 2. The seed layer 6 in particular comprises a high proportion of silver. It may however also entirely be made of pure silver. The seed layer 6 is in particular formed by conductive traces which are applied to the front side 3 of the semiconductor substrate 2 by means of screen printing.

The diffusion barrier 7, which completely covers the seed layer 6, consists of a material, in particular a metal, which has a negligible diffusion coefficient and a negligible miscibility with respect to the material of the seed layer 6. The diffusion barrier 7 comprises at least a proportion of nickel and/or cobalt or an alloy thereof. It has a thickness of few micrometers.

The conductive layer 8 consists of a material with good electrical conductivity. The conductive layer 8 in particular consists of copper. It may however also be partially formed of another material with high electrical conductivity.

The conductive layer 8 is completely covered by the solderable anti-corrosion layer 9. Said anti-corrosion layer 9 prevents corrosive media from attacking the conductive layer 8. The conductive layer 8 may consist of the same material as the seed layer 6. In this case, the diffusion barrier 7 can be omitted. In other words, the conductive layer 8 and the seed layer 6 can be comprised in a single layer. In this case, the anti-corrosion layer 9 has the function of both the anti-corrosion layer and the diffusion barrier. The anti-corrosion layer 9 advantageously consists of a spontaneously self-passivating material. This improves the corrosion protection. The anti-corrosion layer 9 shows good solderability even in the passivated state. It has a thickness of no more than 3 μm, in particular of no more than 2 μm, in particular of no more than 1 μm. The anti-corrosion layer 9 comprises a proportion of nickel. The nickel content advantageously amounts to at least 50%, in particular at least 90%, in particular at least 99%. The anti-corrosion layer 9 may also consist of tin.

The diffusion barrier 7 advantageously has the same chemical composition as the anti-corrosion layer 9. The diffusion barrier 7 may of course also have a chemical composition which differs from that of the anti-corrosion layer 9.

The diffusion barrier 7, the conductive layer 8 and the anti-corrosion layer 9 together form a cover layer 10 which completely covers the seed layer 6 disposed underneath. In particular the diffusion barrier 7 and/or the anti-corrosion layer 9 completely cover the silver-containing seed layer 6. The cover layer 10 thus reliably prevents the seed layer 6 from being penetrated by the material of a solder contact 11 arranged on the anti-corrosion layer 9. The solder contact 11 serves to establish an electrically conducting connection between a connection element 12 and the contact structure 5. The connection element 12 is for instance an electrically conductive copper strip. Alternative connections for establishing contact in a solar cell are of course conceivable as well.

The solder contact 11 is at least partially formed of a solder with a low melting temperature. The solder advantageously has a melting temperature of less than 230° C., in particular less than 180° C., in particular less than 150° C. According to the invention, the solder is based on an alloy containing tin or bismuth, in particular a eutectic tin-bismuth alloy. Slight deviations from the eutectic composition are conceivable as well, in particular if a slightly higher melting temperature of the solder is required for technological reasons. A tin-bismuth-silver alloy is conceivable as well. The cover layer 10, in particular at least one of the diffusion barrier 7 and the anti-corrosion layer 9, prevents the silver-containing conductive traces of the contact structure 5 from being penetrated by bismuth from the solder of the solder contact 11. Furthermore, this prevents leaching of the silver-containing seed layer 6.

The following is a description of a method for the production of the semiconductor component 1, in particular for the production of the solder contact 11. In a first step, the semiconductor substrate 2 is provided with the contact structure 5. A detailed description thereof can be found in DE 10 2008 015 452.0. The semiconductor substrate 2 is provided in a first step, and the seed layer 6 is applied to the front side 3 thereof by means of a screen printing process. Afterwards, the other layers of the contact structure 5 are applied to the semiconductor substrate 2 using electrolytic and/or chemical deposition processes.

In order to establish contact in the semiconductor component 1, the connection element 12 is soldered to the contact structure 5. Soldering takes place by means of the above-described low melting temperature solder. Suitable soldering processes include contact, laser, light and induction soldering.

The solder contact 11 is point-shaped. It may however also have a continuous shape which extends along the conductive trace.

When the connection element 12 is soldered to the contact structure 5, only the localized solder contact 11 is heated up in order to melt the solder. This causes the mechanical stresses occurring in the semiconductor substrate 2 during the cooling process to be reduced even further. It is of course conceivable as well to heat up the entire semiconductor component 1 in order to produce the solder contact 11.

The low melting temperature solder according to the invention ensures very short process times. Producing the solder contact 11 between the connection element 12 and the contact structure 5 requires less than 30 seconds, in particular less than 15 seconds, in particular less than 5 seconds.

When the solder contact is re-melted for module embedding, the cover layer 10 completely prevents the silver layer disposed underneath from penetrating into the bismuth-containing solder contact 11. This reliably prevents detachment of the silver-containing conductive traces which is observed when the cover layer 10 is not provided.

In an alternative embodiment, the contact structures 5 are only arranged on the back side 4 of the semiconductor substrate 2. In this case, the semiconductor component 1 is a back-side contact solar cell.

What is claimed is:

1. A semiconductor component (1) comprising
a. at least one semiconductor substrate (2) comprising
b. at least one contact structure (5) arranged on the semiconductor substrate (2);
c. at least one electrically conducting connection element (12) for establishing electrical contact in the contact structure (5),
d. with the at least one connection element (12) being connected to the at least one contact structure (5) in an electrically conducting manner by means of a solder contact (11); and
e. with the solder contact (11) being at least partially formed by a low melting temperature solder.

2. A semiconductor component (1) according to claim 1, wherein the solder has a melting temperature of less than 230° C.

3. A semiconductor component (1) according to claim 2, wherein the solder has a melting temperature of less than 180° C.

4. A semiconductor component (1) according to claim 2, wherein the solder has a melting temperature of less than 150° C.

5. A semiconductor component (1) according to claim 1, wherein the solder is based on an alloy containing at least one of the group comprising tin and bismuth.

6. A semiconductor component according to claim 5, wherein the solder is based on one of the group comprising a eutectic tin-bismuth and a tin-bismuth-silver alloy.

7. A semiconductor component (1) according to claim 1, wherein the contact structure (5) has a multilayer design.

8. A semiconductor component (1) according to claim 1, wherein the contact structure (5) comprises a copper layer.

9. A semiconductor component (1) according to claim 1, wherein the contact structure (5) comprises a silver layer.

10. A semiconductor component (1) according to claim 1, wherein the contact structure (5) comprises one of the group comprising a nickel layer and a tin layer as uppermost layer.

11. A semiconductor component (1) according to claim 1, wherein the contact structure (5) comprises a cover layer (10) which completely separates a silver-containing layer of the contact structure (5) disposed underneath from the solder contact (11) so as to prevent penetration of said silver-containing layer.

12. A semiconductor component (1) according to claim 1, wherein the at least one solder contact (11) is point-shaped.

13. A semiconductor component (1) according to claim 1, wherein the at least one solder contact (11) is continuous.

14. A semiconductor component (1) according to claim 1, wherein a diffusion barrier (7) is provided which completely covers a seed layer (6) and is of a material which has a negligible diffusion coefficient and a negligible miscibility with respect to the material of the seed layer (6).

15. A semiconductor component (1) according to claim 1, wherein an anti-corrosion layer (9) is provided which completely covers a conductive layer (8).

16. A method for the production of a solder contact (11) with a semiconductor component (1), the method comprising the following steps:
providing the semiconductor component (1) comprising
at least one contact structure (5) and
at least one electrically conducting connection element (12);
soldering the at least one connection element (12) to the at least one contact structure (5),
with a low melting temperature solder being used for soldering.

17. A method according to claim 16, wherein the solder is based on an alloy containing at least one of the group comprising tin and bismuth.

18. A method according to claim 17, wherein the solder is based on an alloy containing one of the group comprising a eutectic tin-bismuth alloy and a tin-bismuth-silver alloy.

19. A method according to claim 16, wherein soldering is performed by means of one of the group comprising contact, laser, light and induction soldering.
